(19) United States
(12) Patent Application Publication
(10) Pub. No.: US 2022/0246658 A1
(43) Pub. Date: Aug. 4, 2022

(54) IMAGE SENSOR AND METHOD FOR MAKING THE SAME

(71) Applicant: Hua Hong Semiconductor (Wuxi) Limited, Wuxi (CN)

(72) Inventors: Xiao FAN, Wuxi (CN); Guanglong CHEN, Wuxi (CN); Han WANG, Wuxi (CN)

(73) Assignee: Hua Hong Semiconductor (Wuxi) Limited, Wuxi (CN)

(21) Appl. No.: 17/584,030

(22) Filed: Jan. 25, 2022

(30) Foreign Application Priority Data
Feb. 4, 2021 (CN) 202110152757.2

(51) Int. Cl. H01L 27/146; H04N 5/369

(52) U.S. Cl. CPC H01L 27/14623; H04N 5/379; H01L 27/14643; H01L 27/14685; H01L 27/1463

(57) ABSTRACT

An image sensor including an isolation structure and a plurality of photodiodes arranged in a photosensitive area. The isolation structure isolates the plurality of the photodiodes from each other to form an array structure, and a closed air cavity structure is formed in the isolation structure between two adjacent photodiodes. A method for manufacturing an image sensor includes: providing a base layer; selectively etching the base layer to form a deep trench in a photosensitive area of the base layer; the deep trench extending from the first surface to the second surface of the base layer in a longitudinal direction to divide the base layer into device units arranged in an array; and gradually growing an epitaxial layer on the surface of the deep trench by means of an epitaxial growth process, so that the space in the deep trench tapers to form a closed air cavity structure.

### CROSS-REFERENCE TO RELATED APPLICATION

This application claims priority to Chinese patent application No. CN 202110152757.2, filed at CNIPA on Feb. 4, 2021, and entitled “IMAGE SENSOR AND METHOD FOR MAKING THE SAME”, the disclosure of which is incorporated herein by reference in its entirety.

### TECHNICAL FIELD

The present application relates to the technical field of semiconductors, and in particular to an image sensor and a method for making the same.

### BACKGROUND

The core structure of a CMOS image sensor is a photoelectric conversion unit, and a core device of the photoelectric conversion unit is a photodiode. Generally, the photoelectric conversion unit of the image sensor includes a plurality of photodiodes arranged in an array. The photodiode can convert collected photons into electrons, and then the electrons are converted into an electrical signal by other auxiliary circuit structures and output.

In the prior art, for photodiodes arranged in an array, two adjacent photodiodes are isolated from each other by an isolation structure to prevent signal crosstalk. The isolation structure includes an isolation well or a deep trench isolation structure.

However, when the incident light irradiates a specific photodiode in the prior art at a certain inclination angle, some light beams in the incident light reach the surface of the isolation structure, and even penetrates through the isolation structure to irradiate the adjacent photodiode, thereby causing the problem of signal crosstalk.

### SUMMARY

A technical problem to be solved by the present application is to provide an image sensor and a method for making the same, to solve this technical problem in the prior art that incident light may penetrate through an isolation structure to irradiate an adjacent photodiode, thereby causing the problem of signal crosstalk.

In one aspect, according to some embodiments in this disclosure, an image sensor includes: an isolation structure and a plurality of photodiodes arranged in a photosensitive area.

The isolation structure isolates the plurality of the photodiodes from each other to form an array structure, and a closed air cavity structure is formed in the isolation structure between two adjacent photodiodes.

In some cases, the photosensitive area of the image sensor includes a light blocking layer and a device layer which are stacked, and the light blocking layer is close to a light entrance side.

The isolation structure includes: a blocking portion in the light blocking layer and an isolation portion in the device layer, the blocking portion and the isolation portion are stacked correspondingly, and the air cavity structure is located in the blocking portion.

In some cases, each of the photodiodes includes: a blocking bottom in the light blocking layer and a device portion in the device layer, and the blocking bottom and the device portion of each of the photodiodes are stacked correspondingly.

In some cases, the isolation portion of the isolation structure isolates the device portions of the adjacent photodiodes from each other.

The blocking portion of the isolation structure isolates the blocking bottoms of the adjacent photodiodes from each other.

In some cases, the array structure of the photodiodes includes a plurality of rows of diodes and a plurality of columns of diodes.

The isolation structure includes a row isolation structure and a column isolation structure, the row isolation structure is located between two adjacent rows of diodes, the column isolation structure is located between two adjacent columns of diodes, and the row isolation structure and the column isolation structure intersect to form a crisscross area.

In some cases, the width of the row isolation structure decreases near the crisscross area, and the width of the column isolation structure decreases near the crisscross area.

In some cases, the air cavity structures in the same row isolation structure are spaced apart at the crisscross area.

The air cavity structures in the same column isolation structure are spaced apart at the crisscross area.

In order to solve the technical problem in the prior art, another aspect of the present application provides a method for manufacturing an image sensor, wherein the method for manufacturing an image sensor includes the following steps: providing a base layer, the base layer including a first surface and a second surface opposite each other; selectively etching the base layer to form a deep trench in a photosensitive area of the base layer; the deep trench extending from the first surface to the second surface of the base layer in a longitudinal direction to divide the base layer into device units arranged in an array; and gradually growing an epitaxial layer on the surface of the deep trench by means of an epitaxial growth process, so that the space in the deep trench tapers to form a closed air cavity structure.

In some cases, the method further includes the following steps: removing a layer covering the first surface of the base layer; forming a device layer on the exposed first surface of the base layer; performing impurity ion implantation of a first conductivity type on a device layer area stacked on the device unit, to form a device portion of a diode; and performing impurity ion implantation of a second conductivity type on a device layer area stacked on the deep trench, wherein an impurity ion implantation area of the second conductivity type isolates the device portions of the adjacent diodes from each other.

In some cases, the deep trench includes a row deep trench and a column deep trench intersecting with each other, and an intersection area of the row deep trench and the column deep trench forms a crisscross area.

The width of the row deep trench decreases near the crisscross area, and the width of the column deep trench decreases near the crisscross area.

The technical solution of the present application at least has the following advantages: the air cavity structure allows light with a certain angle to pass through the isolation structure around the air cavity structure, and total reflection occurs on the surface of the air cavity structure. The reflected light again enters the photodiode irradiated by the light, without entering the adjacent photodiode, thereby reducing crosstalk and significantly improving the optical performance of the image sensor.

### BRIEF DESCRIPTION OF THE DRAWINGS

To more clearly explain the specific implementations of the present application or the technical solution in the prior art, the drawings required in description of the specific implementations or the prior art will be briefly described below. The drawings described below are some implementations of the present application, and those skilled in the art could also obtain other drawings on the basis of these drawings, without involving any inventive skill.

FIG. 1a illustrates a schematic diagram of a cross sectional structure of a partial area of an image sensor in the prior art.

FIG. 1b illustrates a schematic diagram of a longitudinal sectional structure of a partial area of the image sensor in the prior art.

FIG. 2 illustrates a schematic diagram of a longitudinal sectional structure of an image sensor provided by an embodiment of the present application.

FIG. 3 illustrates a schematic diagram of a sectional structure of an image sensor provided by another embodiment of the present application.

FIG. 4 illustrates a schematic diagram of a cross sectional structure of an image sensor provided by an embodiment of the present application.

FIG. 5 illustrates a flowchart of a method for manufacturing an image sensor provided by an embodiment of the present application.

FIG. 6a illustrates a schematic diagram of a sectional structure of a base layer provided by an embodiment of the present application.

FIG. 6b illustrates a schematic diagram of a sectional structure of a device obtained after step S2 of the method for manufacturing an image sensor provided by an embodiment of the present application is completed.

FIG. 6c illustrates a schematic diagram of a sectional structure of a device obtained after step S3 of the method for manufacturing an image sensor provided by an embodiment of the present application is completed.

FIG. 6d illustrates a schematic diagram of a sectional structure of a device obtained after a redundant epitaxial layer on a first surface of a base layer is removed by grinding.

FIG. 6e illustrates a schematic diagram of a sectional structure of a device obtained after step S4 of the method for manufacturing an image sensor provided by an embodiment of the present application is completed.

FIG. 7 illustrates a flowchart of a method for manufacturing an image sensor provided by another embodiment of the present application.

### DETAILED DESCRIPTION OF THE DISCLOSURE

The technical solution of the present application will be clearly and completely described below with reference to the drawings. Obviously, the described embodiments are part of the embodiments of the present application, instead of all of them. Based on the embodiments in the present application, all other embodiments obtained by those skilled in the art without involving any inventive skill shall fall into the protection scope of the present application.

In the description of the present application, it should be noted that the orientation or position relationship indicated by the terms “center”, “upper”, “lower”, “left”, “right”, “vertical”, “horizontal”, “inner”, “outer”, etc. is based on the orientation or position relationship shown in the drawings, intended only for the convenience of describing the present application and simplifying the description, rather than indicating or implying that the apparatus or element referred to necessarily has a specific orientation or is configured or operated in a specific orientation, and thus cannot be construed as a limitation on the present application. In addition, the terms “first”, “second”, and “third” are used for descriptive purposes only and cannot be construed as indicating or implying relative importance.

In the description of the present application, it should be noted that, unless otherwise clearly specified and limited, the terms “mounting”, “coupling”, and “connecting” should be understood in a broad sense, for example, it can be a fixed connection, a detachable connection, or an integrated connection, can be a mechanical connection or an electrical connection, can be a direct connection, an indirect connection implemented by means of an intermedium, or an internal connection between two components, and can be a wireless connection or a wired connection. One skilled in the art could understand the specific meanings of the above terms in the present application on the basis of specific situations.

In addition, the technical features involved in different embodiments of the present application described below can be combined with each other in the case of no conflict.

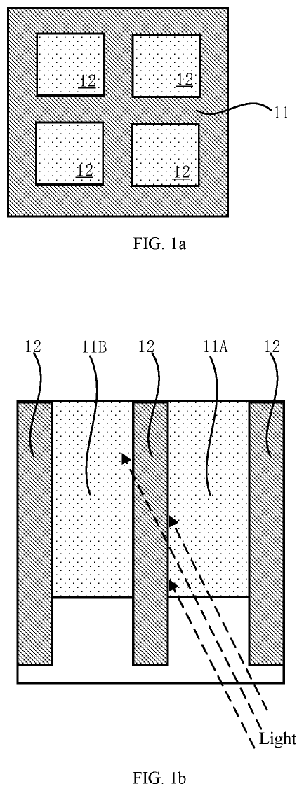

FIG. 1a illustrates a schematic diagram of a cross sectional structure of a partial area of an image sensor in the prior art. Referring to FIG. 1a, the image sensor includes an isolation structure 11 and a plurality of photodiodes 12. The isolation structure 11 isolates the plurality of the photodiodes 12 from each other to form an array structure. FIG. 1b illustrates a schematic diagram of a longitudinal sectional structure of a partial area of the image sensor in the prior art. Referring to FIG. 1b, incident light irradiates the photodiode 11A at a certain inclination angle, and some light beams in the light penetrate the isolation structure 12 and enters the photodiode 11B, thereby causing the problem of signal crosstalk.

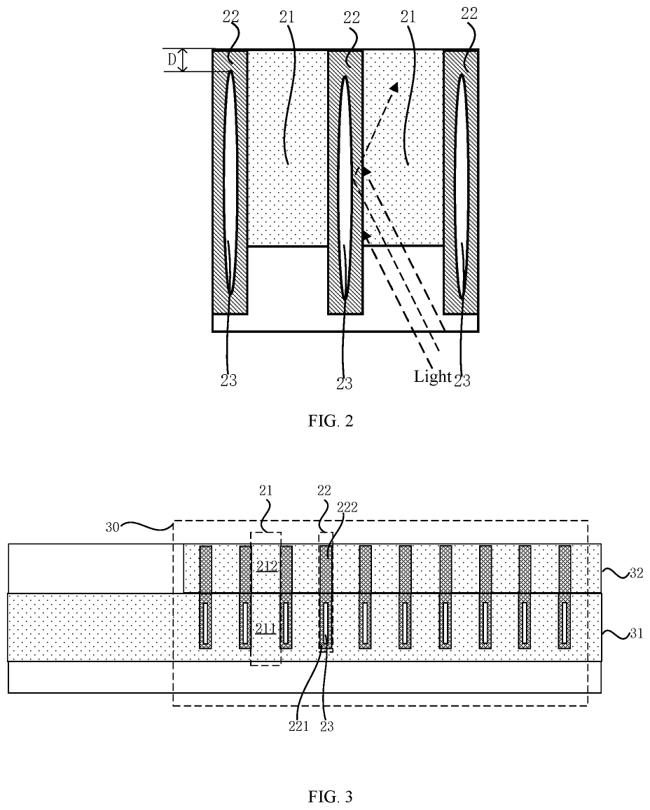

FIG. 2 illustrates a schematic diagram of a longitudinal sectional structure of an image sensor provided by an embodiment of the present application. Referring to FIG. 2, the image sensor includes an isolation structure 22 and a plurality of photodiodes 21 arranged in a photosensitive area. The isolation structure 22 isolates the plurality of the photodiodes 21 from each other to form an array structure, and a closed air cavity structure 23 with a low dielectric constant is formed in the isolation structure 22 between two adjacent photodiodes 21.

The dielectric constant of air in the air cavity structure is much less than that of the isolation structure. The material of the isolation structure around the air cavity structure can be silicon or silicon dioxide, so that light with a certain angle can pass through the isolation structure around the air cavity structure, and total reflection occurs on the surface of the air cavity structure. The reflected light again enters the photodiode irradiated by the light, without entering the adjacent photodiode, thereby reducing crosstalk and significantly improving the optical performance of the image sensor.

FIG. 3 illustrates a schematic diagram of a sectional structure of an image sensor provided by another embodiment of the present application. Referring to FIG. 3, the photosensitive area 30 of the image sensor includes a light blocking layer 31 and a device layer 32 which are stacked, and the light blocking layer 31 is close to a light entrance side. The isolation structure 22 includes: a blocking portion 221 in the light blocking layer 31 and an isolation portion 222 in the device layer 32, the blocking portion 221 and the isolation portion 222 are stacked correspondingly, and the air cavity structure 23 is located in the blocking portion 31. Optionally, a distance D between the upper end of the air cavity structure 23 and a first surface of the base layer is greater than 100 nm.

Still referring to FIG. 3, each photodiode 21 includes: a blocking bottom 211 in the light blocking layer 31 and a device portion 212 in the device layer 32, and the blocking bottom 211 and the device portion 212 of each photodiode 21 are stacked correspondingly.

The isolation portion 222 of the isolation structure 22 isolates the device portions 212 of the adjacent photodiodes 21 from each other, and the blocking portion 221 of the isolation structure 22 isolates the blocking bottoms 211 of the adjacent photodiodes 21 from each other.

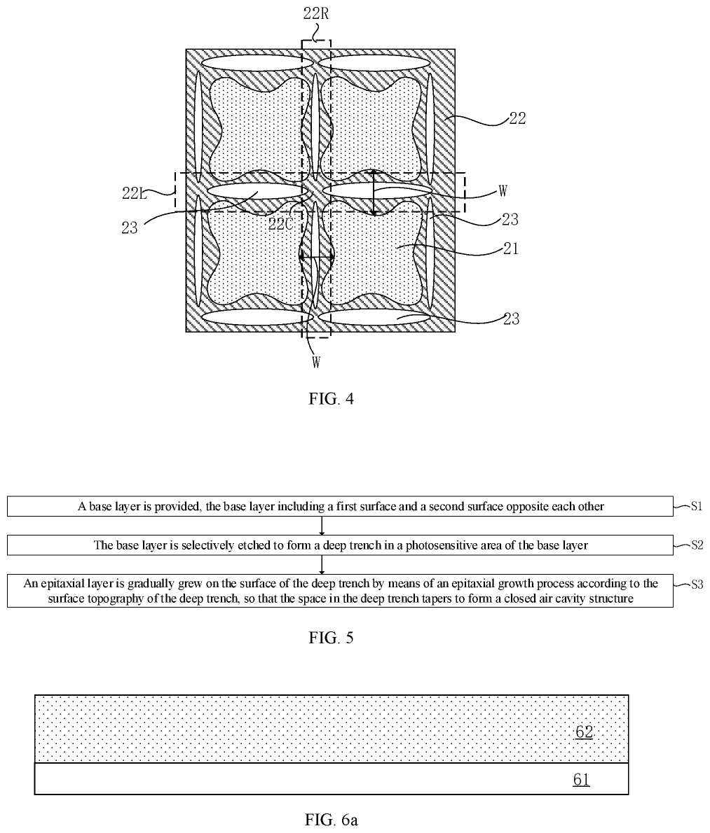

FIG. 4 illustrates a schematic diagram of a cross sectional structure of an image sensor provided by an embodiment of the present application. The array structure of the photodiodes includes a plurality of rows of diodes and a plurality of columns of diodes. The isolation structure 22 includes a row isolation structure 22L and a column isolation structure 22R, the row isolation structure 22L is located between two adjacent rows of diodes, the column isolation structure 22R is located between two adjacent columns of diodes, and the row isolation structure 22L and the column isolation structure 22R intersects to form a crisscross area 22C.

Still referring to FIG. 4, the width W of the isolation structure 22 may be 200 nm to 400 nm, and the depth may be 1.5 um to 3 um. The width W of the row isolation structure 22L gradually decreases near the crisscross area 22C, and the width W of the column isolation structure 22R gradually decreases near the crisscross area 22C. The air cavity structures 23 in the same row isolation structure 22L are spaced apart at the crisscross area 22C; and the air cavity structures 23 in the same column isolation structure 22R are spaced apart at the crisscross area 22C.

FIG. 5 illustrates a flowchart of a method for manufacturing an image sensor provided by an embodiment of the present application. Referring to FIG. 5, the method for manufacturing an image sensor includes the following steps:

Step S1: A base layer is provided, the base layer including a first surface and a second surface opposite each other.

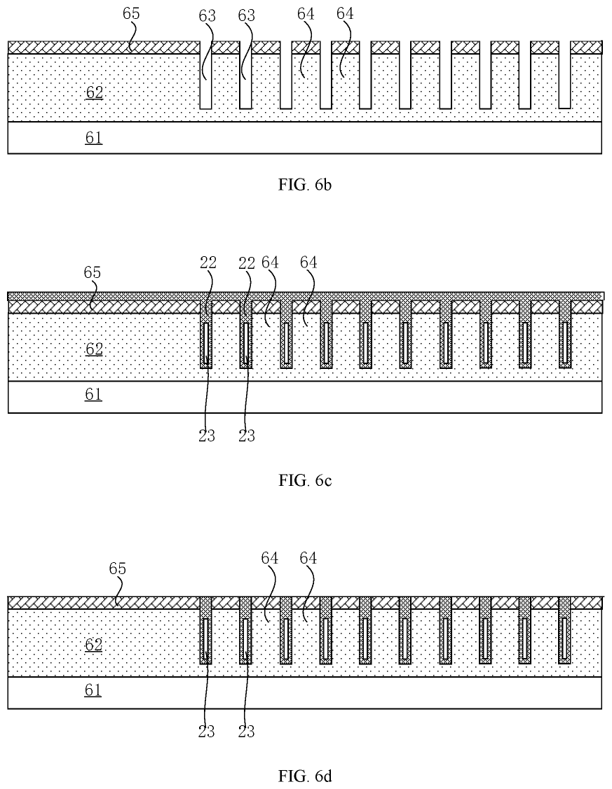

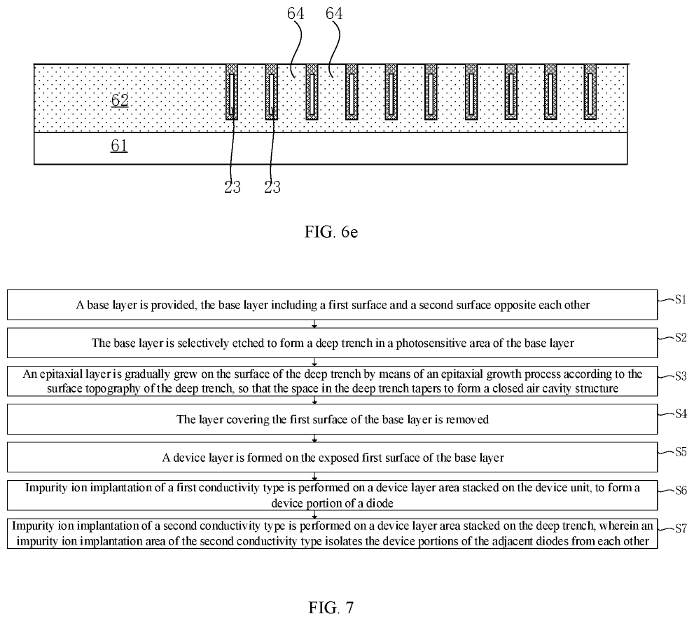

FIG. 6a illustrates a schematic diagram of a sectional structure of the base layer provided by an embodiment of the present application. The base layer includes a substrate layer 61 and an epitaxial layer 62 grown on the substrate layer 61. The upper surface of the epitaxial layer 62 is the first surface of the base layer, and the lower surface of the substrate layer 61 is the second surface of the base layer. The substrate layer 61 may be a silicon substrate, and the epitaxial layer 62 may be an intrinsic epitaxial layer or a doped epitaxial layer. For an N-type photodiode, the conductivity type of the doped epitaxial layer is N-type.

Step S2: The base layer is selectively etched to form a deep trench in a photosensitive area of the base layer.

FIG. 6b illustrates a schematic diagram of a sectional structure of a device obtained after step S2 of the method for manufacturing an image sensor provided by an embodiment of the present application is completed. The deep trench 63 is formed in the epitaxial layer 62 of the base layer, and the deep trench 63 extends downward from the upper surface of the epitaxial layer 62. That is, the deep trench 63 extends from the first surface to the second surface of the base layer in a longitudinal direction to divide the base layer into device units arranged in an array. The device unit 64 is an area used for forming a photodiode.

In this embodiment, step S2 can be performed according to the following steps:

First, a mask layer 65 is formed on the upper surface of the epitaxial layer 62 shown in FIG. 6a. The mask layer 65 may be silicon dioxide or silicon nitride.

Secondly, the mask layer 65 is coated with a photoresist, and a deep trench pattern is defined using the photoresist by means of a photolithography process.

Thirdly, the mask layer 65 is etched according to the deep trench pattern, so that the deep trench pattern is transferred to the mask layer 65.

Finally, the epitaxial layer 62 is etched according to the deep trench pattern on the mask layer 65, so that the deep trench 63 as shown in FIG. 6b is formed in the epitaxial layer 62.

In this embodiment, the deep trench includes a row deep trench and a column deep trench intersecting with each other, and an intersection area of the row deep trench and the column deep trench forms a crisscross trench. The width of the row deep trench decreases near the crisscross trench, and the width of the column deep trench decreases near the crisscross trench. The width of the deep trench may be 200 nm to 400 nm, and the depth may be 1.5 um to 3 um.

Step S3: An epitaxial layer is gradually grown on the surface of the deep trench by means of an epitaxial growth process, so that the space in the deep trench tapers to form a closed air cavity structure.

FIG. 6c illustrates a schematic diagram of a sectional structure of a device obtained after step S3 of the method for manufacturing an image sensor provided by an embodiment of the present application is completed. A closed air cavity structure 23 is formed in the isolation structure 22 between two adjacent device units 64. Optionally, a distance D between the upper end of the air cavity structure 23 and the first surface of the base layer is greater than 100 nm.

In this embodiment, since the width of the row deep trench gradually decreases near the crisscross area, and the width of the column deep trench gradually decreases near the crisscross section, the epitaxial layer formed in step S3 fills up the deep trench at the crisscross area in advance, so that the finally formed closed air cavity structures are spaced apart at the position of the crisscross trench. Referring to FIG. 4, after step S3 is completed, the row isolation structure 22L shown in FIG. 4 is formed at the position of the row deep trench, the column isolation structure 22R shown in FIG. 4 is formed at the position of the column deep trench position, the crisscross area 22C shown in FIG. 4 is formed is formed at the position of the crisscross trench, and the air cavity structures are spaced apart at the crisscross area 22C.

It needs to be explained that, due to the characteristics of the epitaxial growth process, at the opening of the deep trench, the concentration of a chemical gas used to deposit and form the epitaxial layer in the deep trench is relatively high, so that the epitaxial layer grows faster at the opening of the deep trench. In this case, the deep trench is closed at a position close to the opening of the deep trench, so that the epitaxial layer grown in the deep trench can form the closed air cavity structure. By controlling the concentration gradient of the chemical gas at the opening of the deep trench, the distance between the upper end of the air cavity structure and the first surface of the base layer can be controlled.

During the epitaxial growth process of step S3, when the epitaxial layer is gradually grown on the surface of the deep trench, the epitaxial layer can form a concentration gradient in a growth direction by controlling the doping concentration of the epitaxial layer.

On the basis of the embodiment shown in FIG. 5, FIG. 7 illustrates a flowchart of a method for manufacturing an image sensor provided by another embodiment of the present application. The method for manufacturing an image sensor further includes the following steps performed after step S3:

Step S4: The layer covering the first surface of the base layer is removed.

In this embodiment, chemical mechanical polishing may be first performed on the structure shown in FIG. 6c, to remove the redundant epitaxial layer which is formed on the first surface of the base layer after step S3 is completed, thereby forming the structure shown in FIG. 6d. FIG. 6d illustrates a schematic diagram of a sectional structure of a device obtained after the redundant epitaxial layer on the first surface of the base layer is removed by grinding. Secondly, the mask layer 65 covering the first surface of the base layer is removed by means of wet etching, so that the first surface of the base layer is exposed. Then, the exposed first surface of the base layer can be planarized by means of chemical mechanical polishing, thereby forming the structure shown in FIG. 6e. FIG. 6e illustrates a schematic diagram of a sectional structure of a device obtained after step S4 is completed.

Step S5: A device layer is formed on the exposed first surface of the base layer.

Step S6: Impurity ion implantation of a first conductivity type is performed on a device layer area stacked on the device unit, to form a device portion of a diode.

Step S7: Impurity ion implantation of a second conductivity type is performed on a device layer area stacked on the deep trench, wherein an impurity ion implantation area of the second conductivity type isolates the device portions of the adjacent diodes from each other.

In this embodiment, impurity ions of the first conductivity type may be N-type impurity ions, and impurity ions of the second conductivity type may be P-type impurity ions. The thickness of the device layer can be 1 um to 2 um.

After step S7 is completed, the device structure shown in FIG. 3 is formed. Still referring to FIG. 3, the light blocking layer 31 shown in FIG. 3 is formed in the base layer, and the device layer 32 is formed on the light blocking layer 31. The light blocking layer 31 is close to a light entrance side. In step S7, impurity ion implantation of the first conductivity type is performed on the device layer 32 to form the device portion 212 of the photodiode 21, and impurity ion implantation of the second conductivity type is performed to form the isolation portion 222 of the isolation structure 22. After step S3 is completed, the blocking portion 221 of the isolation structure 22 is formed in the deep trench. The isolation portion 222 is correspondingly stacked on the blocking portion 221. The photodiode 21 is formed in the device unit, the blocking bottom 211 of the photodiode 21 is formed in the device unit in the light blocking layer 31, and the device portion 212 of the photodiode 21 is correspondingly stacked on the blocking bottom 211.

In this embodiment, the air cavity structure is formed in the deep trench, so that light with a certain angle can pass through the isolation structure around the air cavity structure, and total reflection occurs on the surface of the air cavity structure. The reflected light again enters the photodiode irradiated by the light, without entering the adjacent photodiode, thereby reducing crosstalk and significantly improving the optical performance of the image sensor.

Obviously, the above embodiments are merely examples used for clear description, rather than for limitation on the implementations. Those skilled in the art could also make other changes or modifications in different forms on the basis of the above description. There is no need and way to exhaustively list all of the implementations herein, but obvious changes or modifications derived herefrom still fall within the protection scope created by the present application.

What is claimed is:

1. An image sensor, wherein the image sensor includes: an isolation structure and a plurality of photodiodes arranged in a photosensitive area; and the isolation structure isolates the plurality of the photodiodes from each other to form an array structure, and a closed air cavity structure is formed in the isolation structure between two adjacent photodiodes.

2. The image sensor according to claim 1, wherein the photosensitive area of the image sensor includes a light blocking layer and a device layer which are stacked, and the light blocking layer is close to a light entrance side; and the isolation structure includes: a blocking portion in the light blocking layer and an isolation portion in the device layer, the blocking portion and the isolation portion are stacked correspondingly, and the air cavity structure is located in the blocking portion.

3. The image sensor according to claim 2, wherein each of the photodiodes includes: a blocking bottom in the light blocking layer and a device portion in the device layer, and the blocking bottom and the device portion of each of the photodiodes are stacked correspondingly.

4. The image sensor according to claim 3, wherein the isolation portion of the isolation structure isolates the device portions of the adjacent photodiodes from each other; and the blocking portion of the isolation structure isolates the blocking bottoms of the adjacent photodiodes from each other.

5. The image sensor according to claim 1, wherein the array structure of the photodiodes includes a plurality of rows of diodes and a plurality of columns of diodes; and the isolation structure includes a row isolation structure and a column isolation structure, the row isolation structure is located between two adjacent rows of diodes, the column isolation structure is located between two adjacent columns of diodes, and the row isolation structure and the column isolation structure intersects to form a crisscross area.

6. The image sensor according to claim 5, wherein the width of the row isolation structure decreases near the crisscross area, and the width of the column isolation structure decreases near the crisscross area.

7. The image sensor according to claim 5, wherein the air cavity structures in the same row isolation structure are spaced apart at the crisscross area; and the air cavity structures in the same column isolation structure are spaced apart at the crisscross area.

8. A method for manufacturing an image sensor, wherein the method for manufacturing an image sensor includes the following steps: providing a base layer, the base layer including a first surface and a second surface opposite each other; selectively etching the base layer to form a deep trench in a photosensitive area of the base layer; the deep trench extending from the first surface to the second surface of the base layer in a longitudinal direction to divide the base layer into device units arranged in an array; and gradually growing an epitaxial layer on the surface of the deep trench by means of an epitaxial growth process, so that the space in the deep trench tapers to form a closed air cavity structure.

9. The method for manufacturing an image sensor according to claim 8, further including the following steps:
removing the layer covering the first surface of the base layer;
forming a device layer on the exposed first surface of the base layer;
performing impurity ion implantation of a first conductivity type on a device layer area stacked on the device unit, to form a device portion of a diode; and
performing impurity ion implantation of a second conductivity type on a device layer area stacked on the deep trench, wherein an impurity ion implantation area of the second conductivity type isolates the device portions of the adjacent diodes from each other.

10. The method for manufacturing an image sensor according to claim 8, wherein the deep trench includes a row deep trench and a column deep trench intersecting with each other, and an intersection area of the row deep trench and the column deep trench forms a crisscross area; and the width of the row deep trench decreases near the crisscross area, and the width of the column deep trench decreases near the crisscross area.
